(19) United States
(12) Patent Application Publication
(10) Pub. No.: US 2024/0329526 A1
(43) Pub. Date: Oct. 3, 2024

(54) PHOTOSENSITIVE RESIN COMPOSITION, PHOTOSENSITIVE RESIN LAYER USING THE SAME, AND COLOR FILTER

(71) Applicant: SAMSUNG SDI CO., LTD., Yongin-si (KR)

(72) Inventors: Eunbi PARK, Suwon-si (KR); Jihye KWON, Suwon-si (KR); Ickjin KIM, Suwon-si (KR); Hyuksin KWON, Suwon-si (KR); Donghyun PARK, Suwon-si (KR); Youngmin JEON, Suwon-si (KR); Juho JUNG, Suwon-si (KR); Baek Soung PARK, Suwon-si (KR)

(21) Appl. No.: 18/376,500

(22) Filed: Oct. 4, 2023

(30) Foreign Application Priority Data
Mar. 21, 2023 (KR) 10-2023-0036792

(51) Int. Cl. G03F 7/028; C08F 2/44; C08F 2/50; G02B 5/22; G03F 7/00; G03F 7/033

(52) U.S. Cl. CPC G03F 7/028; C08F 2/44; C08F 2/50; G02B 5/223; G03F 7/0007; G03F 7/033

(57) ABSTRACT

A photosensitive resin composition includes a photopolymerizable compound; a photopolymerization initiator; a colorant; a binder resin; and a solvent, wherein the photopolymerizable compound includes a first photopolymerizable compound having 4 functional groups, a second photopolymerizable compound having 6 functional groups, and a third photopolymerizable compound having 8 or more functional groups, and the photopolymerizable compound satisfies Equation 1:

$$( x + z ) / y > 1 \qquad [ Equation 1 ]$$

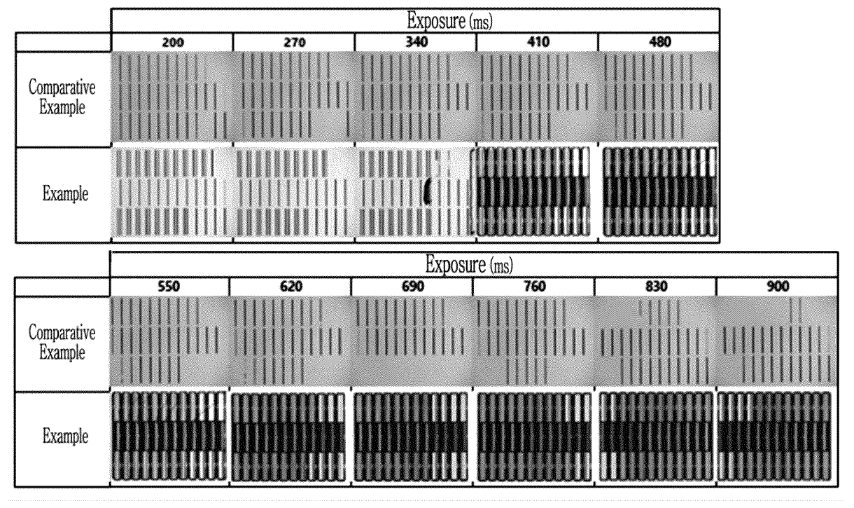

in Equation 1, x is the wt % of the first photopolymerizable compound based on a total weight of the photopolymerizable compound; y is the wt % of the second photopolymerizable compound based on the total weight of the photopolymerizable compound; and z is the wt % of the third photopolymerizable compound based on the total weight of the photopolymerizable compound.

### CROSS-REFERENCE TO RELATED APPLICATION

This application claims priority to and the benefit of Korean Patent Application No. 10-2023-0036792 filed in the Korean Intellectual Property Office on Mar. 21, 2023, the entire contents of which are incorporated herein by reference.

### BACKGROUND

### 1. Field

Embodiments relate to a photosensitive resin composition, a photosensitive resin layer manufactured using the photosensitive resin composition, and a color filter.

### 2. Description of the Related Art

An image sensor may be a semiconductor that converts photons into electrons and displays them on a display device or stores them in a storage device.

The image sensor may be, e.g., a charge coupled device (CCD) image sensor or a complementary metal-oxide semiconductor (CMOS) image sensor, according to a manufacturing process and an application method.

The complementary metal-oxide semiconductor (CMOS) image sensor (CIS), which is a non-memory semiconductor that converts an image received by a camera to a digital signal, may be a collection of pixels such as a color filter, a photodiode, an amplifier, or the like.

The color filter may include filter segments of additively blended primary colors of red, green, and blue,

### SUMMARY

The embodiments may be realized by providing a photosensitive resin composition includes a photopolymerizable compound; a photopolymerization initiator; a colorant; a binder resin; and a solvent, wherein the photopolymerizable compound includes a first photopolymerizable compound having 4 functional groups, a second photopolymerizable compound having 6 functional groups, and a third photopolymerizable compound having 8 or more functional groups, and the photopolymerizable compound satisfies Equation 1:

$$( x + z ) / y > 1 \qquad [ Equation 1 ]$$

in Equation 1, x is the wt % of the first photopolymerizable compound based on a total weight of the photopolymerizable compound; y is the wt % of the second photopolymerizable compound based on the total weight of the photopolymerizable compound; and z is the wt % of the third photopolymerizable compound based on the total weight of the photopolymerizable compound.

The embodiments may be realized by providing a photosensitive resin layer manufactured using the photosensitive resin composition according to an embodiment.

The embodiments may be realized by providing a color filter including a photosensitive resin layer according to an embodiment.

The embodiments may be realized by providing a CMOS image sensor including the color filter according to an embodiment.

### BRIEF DESCRIPTION OF THE DRAWING

The FIGURE shows optical microscopic images of a bulk region (magnification: 2.5) and a fine pattern portion (magnification: 2.5) of Example 3 and Comparative Example 5, respectively.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not necessarily an exclusive term, e.g., “A or B” would include A, B, or A and B.

As used herein, when specific definition is not otherwise provided, “substituted” refers to replacement of at least one hydrogen of a compound by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, “heterocycloalkyl group”, “heterocycloalkenyl group”, “heterocycloalkynyl group,” and “heterocycloalkylene group” refer to presence of at least one N, O, S, or P in a cyclic compound of cycloalkyl, cycloalkenyl, cycloalkynyl, and cycloalkylene.

As used herein, when specific definition is not otherwise provided, “(meth)acrylate” refers to both “acrylate” and “methacrylate”.

In the chemical formulae of the present specification, unless a specific definition is otherwise provided, hydrogen is boned at the position when a chemical bond is not drawn where supposed to be given, and * is a linking point.

### (Photosensitive Resin Composition)

Some embodiments may provide a photosensitive resin composition including, e.g., (A) a photopolymerizable compound; (B) a colorant; (C) a binder resin; (D) a photopolymerization initiator; and (E) a solvent. In an implementation, the (A) photopolymerizable compound may include, e.g., (A-1) a first photopolymerizable compound having 4 functional groups, (A-2) a second photopolymerizable compound having 6 functional groups, and (A-3) a third photopolymerizable compound having 8 or more functional groups.

An adhesion force of a photosensitive resin composition or a photosensitive resin layer to a substrate may have a trade-off relationship with pattern residues of the photosensitive resin layer. The photosensitive resin composition according to some embodiments may include the three kinds of photopolymerizable compounds to help improve the adhesion force of the photosensitive resin composition or a photosensitive resin layer to a substrate and simultaneously, minimize pattern residues of the photosensitive resin layer, when formed into a color filter.

In an implementation, in the three photopolymerizable compounds, as the number of functional groups increase, there may be more interactions with the substrate, which may be advantageous to the adhesion force of the photosensitive resin composition during the coating process; and as the number of the functional groups decreases, the photosensitive resin layer may be less shrunk due to low curing degrees during the developing process, significantly reducing the pattern residues.

The photosensitive resin composition according to some embodiments may use the mixture of three photopolymerizable compounds but controls their mixing ratio within an appropriate range to take an advantage of each photopolymerizable compound but compensate its disadvantage and thus improve the adhesion force of the photosensitive resin composition or the photosensitive resin layer to the substrate and the pattern residues of the photosensitive resin layer, harmoniously.

In an implementation, the photosensitive resin composition according to some embodiments may satisfy Equation 1.

$$( x + z ) / y > 1 \qquad [ Equation 1 ]$$

In Equation 1, x is a content (wt %) of the first photopolymerizable compound based on a total weight of the photopolymerizable compound; y is a content (wt %) of the second photopolymerizable compound based on the total weight of the photopolymerizable compound; and z is a content (wt %) of the third photopolymerizable compound based on the total weight of the photopolymerizable compound.

The third photopolymerizable compound having the largest number of functional groups may be bulky, and as its content is increased, the pattern residues of the photosensitive resin layer could be increased, when manufactured into a color filter. In order to compensate for this, the photosensitive resin composition according to some embodiments should further satisfy Equation 2.

$$( x + y ) / z > 1 \qquad [ Equation 2 ]$$

In in Equation 2, x, y, and z may be the same as defined above.

A weight ratio of the (A-1) first photopolymerizable compound and the (A-3) third photopolymerizable compound in the (A) photopolymerizable compound may be about 9:1 to about 6:4, e.g., about 8:2 to about 6:4. Thereby, for the reasons mentioned above, while taking advantage of the third photopolymerizable compound having the largest number of functional groups, the disadvantages thereof may be compensated for by the first photopolymerizable compound having the smallest number of functional groups.

Based on a total weight of the (A) photopolymerizable compound, the (A-1) first photopolymerizable compound may be included in an amount of about 35 to about 60 wt %, e.g., about 40 to about 55 wt %, or about 40 to about 50 wt %; the (A-2) second photopolymerizable compound may be included in an amount of about 35 to about 55 wt %, e.g., about 35 to about 50 wt %, or about 30 to about 40 wt %; and the (A-3) third photopolymerizable compound may be included in an amount of about 10 to about 30 wt %, e.g., about 15 to about 30 wt %, or about 15 to about 25 wt %.

When Equation 1 and Equation 2 are simultaneously satisfied while satisfying these ranges, the above-mentioned effects can be further harmoniously improved.

Hereinafter, each component constituting the photosensitive resin composition of some embodiments will be described in more detail.

### [(A) Photopolymerizable Compound]

### (A-1) First Photopolymerizable Compound

The (A-1) first photopolymerizable compound may be represented by Chemical Formula 1.

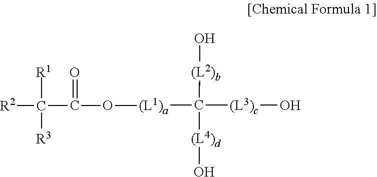

Descriptions of Chemical Formula 1 is as follows.

L¹ to L⁴ may each independently be or include, e.g., a C1 to C20 alkylene oxide group. a to d may each independently be, e.g., an integer of 1 to 10. In an implementation, all of L¹ to L⁴ may be an ethylene oxide group and all of a to d may be 1, e.g., *—OCH₂CH₂—*.

One of R¹ to R³ may be or include, e.g., hydrogen or a substituted or unsubstituted C1 to C20 alkyl group. In an implementation, one of R¹ to R³ may be a substituted or unsubstituted C1 to C20 alkyl group, e.g., methyl.

The other two of R¹ to R³ may each independently be, e.g., a group represented by Chemical Formula A.

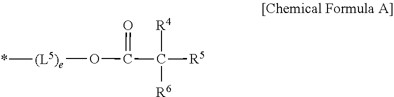

Descriptions of Chemical Formula A is as follows.

L⁵ may be, e.g., a substituted or unsubstituted C1 to C20 alkylene group or a C1 to C20 alkylene oxide group. In an implementation, when L⁵ is a substituted or unsubstituted C1 to C20 alkylene group, e may be 1, and when L⁵ is a C1 to C20 alkylene oxide group, e may be an integer of 1 to 10. In an implementation, L⁵ may be an unsubstituted C1 alkylene, e.g., *—CH₂—*.

One of R⁴ to R⁶ may be, e.g., hydrogen or a substituted or unsubstituted C1 to C20 alkyl group. In an implementation, one of R⁴ to R⁶ may be a substituted or unsubstituted C1 to C20 alkyl group, e.g., methyl.

The other two of R⁴ to R⁶ may each independently be, e.g., a (meth)acrylate group.

Representative examples of the (A-1) first photopolymerizable compound may be as follows.

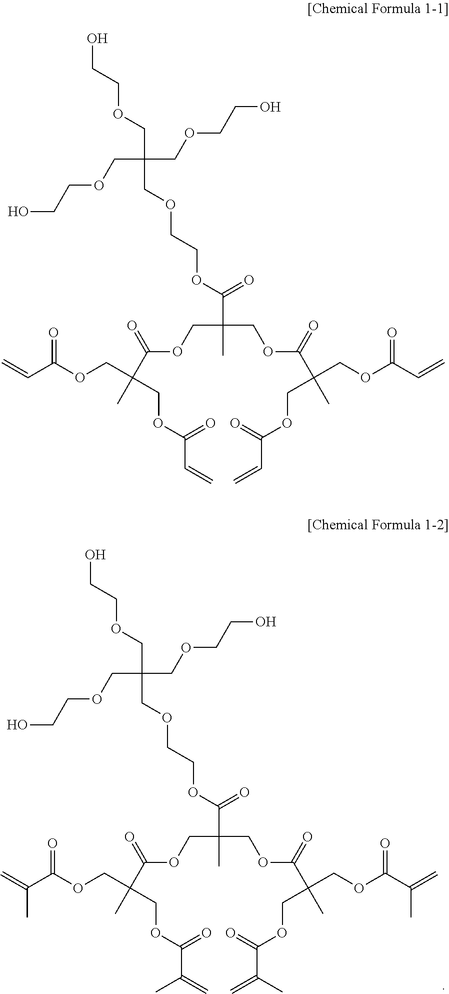

### (A-2) Second Photopolymerizable Compound

The (A-2) second photopolymerizable compound may be, e.g., represented by Chemical Formula 2:

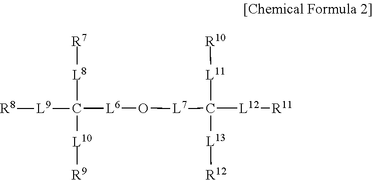

Descriptions of Chemical Formula 2 is as follows.

L⁶ to L¹³ may each independently be or include, e.g., a substituted or unsubstituted C1 to C20 alkylene group. In an implementation, all of L⁶ to L¹³ may be a C1 alkylene group, e.g., *—CH₂—*.

R⁷ to R¹² may each independently be, e.g., a (meth)acrylate group.

Representative examples of the (A-2) second photopolymerizable compound may be as follows.

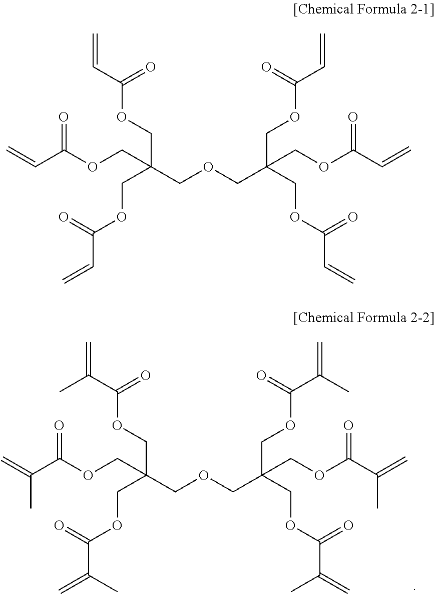

The second photopolymerizable compound represented by Chemical Formula 2-1 may be dipentaerythritol hexaacrylate (DPHA, CAS #: 29570-58-9).

### (A-3) Third Photopolymerizable Compound

The (A-3) third photopolymerizable compound may have 14 functional groups and may be represented by Chemical Formula 3:

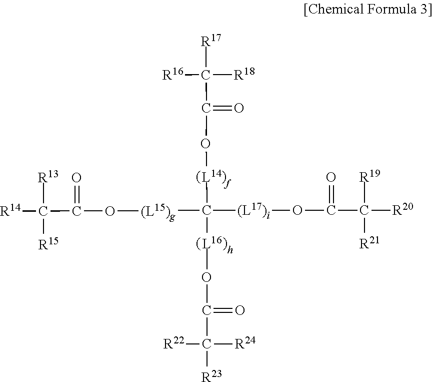

Descriptions of Chemical Formula 3 is as follows.

L¹⁴ to L¹⁷ may each independently be or include, e.g., a C1 to C20 alkylene oxide group. f to i may each independently be, e.g., an integer of 1 to 10. In an implementation, all of L¹⁴ to L¹⁷ may be an ethylene oxide group and all of f to i may be 1, e.g., *—OCH₂CH₂—*.

One of R¹³ to R¹⁵ may be, e.g., hydrogen or a substituted or unsubstituted C1 to C20 alkyl group. In an implementation, one of R¹³ to R¹⁵ may be a substituted or unsubstituted C1 to C20 alkyl group, e.g., methyl.

The other two of R¹³ to R¹⁵ may each independently be, e.g., a group represented by Chemical Formula A.

One of R¹⁶ to R¹⁸ may be, e.g., hydrogen or a substituted or unsubstituted C1 to C20 alkyl group. In an implementation, one of R¹⁶ to R¹⁸ may be a substituted or unsubstituted C1 to C20 alkyl group, e.g., methyl.

Another one of R¹⁶ to R¹⁸ may be, e.g., a group represented by Chemical Formula A, and yet another one may be, e.g., a group represented by Chemical Formula B.

One of R¹⁹ to R²¹ may be, e.g., hydrogen or a substituted or unsubstituted C1 to C20 alkyl group. In an implementation, one of R¹⁹ to R²¹ may be a substituted or unsubstituted C1 to C20 alkyl group, e.g., methyl.

The other two of R¹⁹ to R²¹ may each independently be, e.g., a group represented by Chemical Formula A.

One of R²² to R²⁴ may be, e.g., hydrogen or a substituted or unsubstituted C1 to C20 alkyl group. In an implementation, one of R²² to R²⁴ may be a substituted or unsubstituted C1 to C20 alkyl group, e.g., methyl.

Another one of R²² to R²⁴ may be a group represented by Chemical Formula A and yet another one may be a group represented by Chemical Formula B.

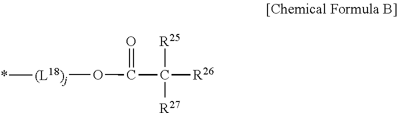

The description of Chemical Formula A is as described above, and the description of Chemical Formula B is as follows:

L¹⁸ may be or may include, e.g., a substituted or unsubstituted C1 to C20 alkylene group or a C1 to C20 alkylene oxide group. In an implementation, when L¹⁸ is a substituted or unsubstituted C1 to C20 alkylene group, j may be 1, and when L¹⁸ is a C1 to C20 alkylene oxide group, j may be an integer of 1 to 10. In an implementation, L¹⁸ may be a unsubstituted C1 alkylene group, e.g., *—CH₂—*.

One of R²⁵ to R²⁷ may be hydrogen or substituted or unsubstituted C1 to C20 alkyl group. In an implementation, one of R²⁵ to R²⁷ may be substituted or unsubstituted C1 to C20 alkyl group, e.g., methyl.

Another one of R²⁵ to R²⁷ may be a C1 to C20 alkyl group substituted with a hydroxy group at the terminal end, e.g., a C1 alkyl substituted with a hydroxy group at the terminal end, or *—CH₂—OH.

Yet another one of R²⁵ to R²⁷ may be a (meth)acrylate group.

Representative examples of the (A-3) third photopolymerizable compound may be as follows.

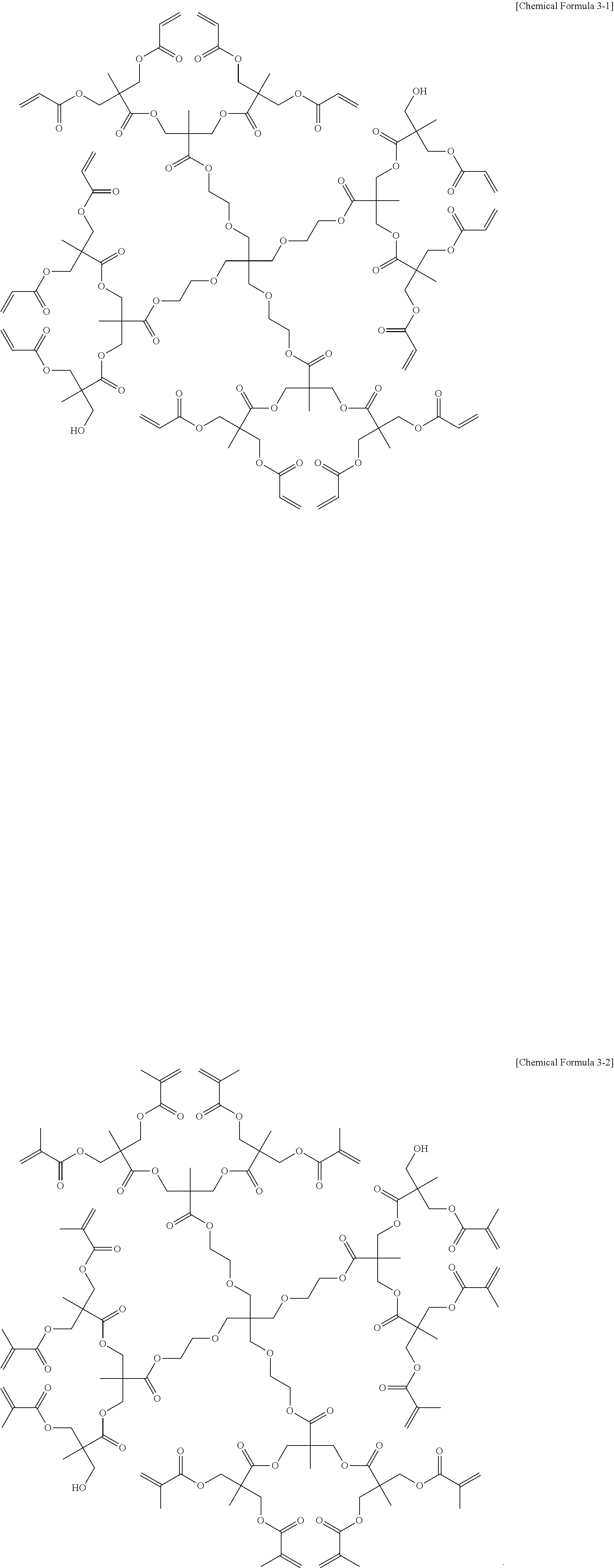

In an implementation, the photopolymerizable compound may additionally include a monofunctional or multifunctional ester of (meth)acrylic acid having at least one ethylenically unsaturated double bond, in addition to the above compounds.

The added photopolymerizable compound may have the ethylenically unsaturated double bond, so that it may form a pattern having excellent heat resistance, light resistance, and chemical resistance by causing sufficient polymerization during exposure in the pattern forming process.

Examples of the added photopolymerizable compound may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Examples of commercially available products of the added photopolymerizable compound may be as follows. The mono-functional (meth)acrylic acid ester may include Aronix M-101®, Aronix M-111®, Aronix M-114® (Toagosei Chemistry Industry Co., Ltd.); KAYARAD TC-110S®, KAYARAD TC-120S® (Nippon Kayaku Co., Ltd.); V-158®, V-2311® (Osaka Organic Chemical Ind., Ltd.), and the like. Examples of a difunctional (meth)acrylic acid ester may include Aronix M-210®, Aronix M-240®, Aronix M-6200® (Toagosei Chemistry Industry Co., Ltd.), KAYARAD HDDA®, KAYARAD HX-220®, KAYARAD R-604® (Nippon Kayaku Co., Ltd.), V-260®, V-312®, V-335 HP® (Osaka Organic Chemical Ind., Ltd.), and the like. Examples of a tri-functional (meth)acrylic acid ester may include Aronix M-309®, Aronix M-400®, Aronix M-405®, Aronix M-450®, Aronix M-710®, Aronix M-8030®, Aronix M-8060® (Toagosei Chemistry Industry Co., Ltd.); KAYARAD TMPTA®, KAYARAD DPCA-20®, KAYARAD DPCA-30®, KAYARAD DPCA-60®, KAYARAD DPCA-120® (Nippon Kayaku Co., Ltd.); V-295®, V-300®, V-360®, V-GPT®, V-3PA®, V-400® (Osaka Yuki Kayaku Kogyo Co. Ltd.), and the like. These may be used alone or as a mixture of two or more.

The added photopolymerizable compound may be treated with acid anhydride to help improve developability.

The added photopolymerizable compound may be included in an amount of about 0.1 wt % to about 5 wt %, e.g., about 1 wt % to about 4 wt %, or about 2 wt % to about 3 wt %, based on the total weight of the photosensitive resin composition. When the photopolymerizable compound is included within the above ranges, sufficient curing may occur during exposure in the pattern forming process, resulting in excellent reliability and excellent developability with an alkali developing solution.

### [(B) Photopolymerization Initiator]

The photopolymerization initiator may be an initiator suitably used in a photosensitive resin composition, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyldimethylketal, and the like.

Examples of the triazine compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include O-acyloxime-based compound, 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

In an implementation, the photopolymerization initiator may further include a carbazole compound, a diketone compound, a sulfonium borate compound, a diazo compound, an imidazole compound, a biimidazole compound, a fluorene compound, or the like in addition to the compounds.

The photopolymerization initiator may be used with a photosensitizer capable of causing a chemical reaction by absorbing light and becoming excited and then, transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 5 wt %, e.g., about 0.5 wt % to about 4 wt %, or about 0.1 wt % to about 3 wt %, based on the total weight of the photosensitive resin composition. When the photopolymerization initiator is included within the ranges, sufficient photopolymerization may occur during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

### [(C) Colorant]

The colorant may include a pigment, and in this case, the resin composition of some embodiments may be a pigment composition. The pigment may be a red pigment, a green pigment, a blue pigment, a yellow pigment, a black pigment, or the like.

Examples of the red pigment may include C.I. Red Pigment 254, C.I. Red Pigment 255, C.I. Red Pigment 264, C.I. Red Pigment 270, C.I. Red Pigment 272, C.I. Red Pigment 177, C.I. Red pigment 89, and the like. Examples of the green pigment include C.I. Green Pigment 7, C.I. Green Pigment 36, C.I. Green Pigment 58, C.I. Green Pigment 59, and the like. Examples of the blue pigment may include copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 16, and the like. Examples of the yellow pigment may include an isoindoline pigment such as C.I. Yellow Pigment 139, and the like, a quinophthalone pigment such as C.I. Yellow Pigment 138, a nickel complex pigment such as C.I. Yellow Pigment 150. Examples of the black pigment may include aniline black, perylene black, titanium black, and carbon black. The above pigments may be used alone or in combination of two or more thereof. In an implementation, as the pigment, a green pigment, a yellow pigment, or a mixture thereof may be used.

The pigment may be included in the photosensitive resin composition for color filters in the form of a dispersion. The pigment dispersion may be composed of the pigment, a solvent, a dispersant, and a dispersion resin. The solid pigment may be included in an amount of about 5 wt % to about 20 wt %, e.g., about 8 wt % to about 15 wt %, based on a total weight of the pigment dispersion.

The solvent may include ethylene glycol acetate, ethyl cellosolve, propylene glycol methyl ether acetate, ethyl lactate, polyethylene glycol, cyclohexanone, propylene glycol methyl ether, or the like. In an implementation, propylene glycol methyl ether acetate may be used.

The dispersant may help to uniformly disperse the pigment in the dispersion, and each of a nonionic, anionic, or cationic dispersant may be used. In an implementation, polyalkylene glycol or esters thereof, polyoxyalkylene, a polyhydric alcohol ester alkylene oxide adduct, an alcohol alkylene oxide adduct, a sulfonic acid ester, a sulfonic acid salt, a carboxylic acid ester, a carboxylic acid salt, an alkyl amide alkylene oxide adduct, alkyl amine, or the like may be used, and these may be used alone or in a mixture of two or more.

The dispersion resin may include an acrylic resin containing a carboxy group, which may improve stability of the pigment dispersion and also improve pixel patternability.

The colorant may further include a dye while including the pigment, and in this case, the resin composition of some embodiments may be a hybrid composition. In an implementation, the dye may include a metal complex dye.

The metal complex dye may be a compound having maximum absorbance in the wavelength range of about 200 nm to about 650 nm, and when the compound has absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of about 530 nm to about 680 nm, a yellow dye having maximum absorbance in a wavelength range of about 200 nm to about 400 nm, an orange dye having a maximum absorbance in a wavelength range of about 300 nm to about 500 nm, a red dye having maximum absorbance in a wavelength range of about 500 nm to about 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include, e.g., Mg, Ni, Cu, Co, Zn, Cr, Pt, Pd, or Fe.

The metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, and the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, and Solvent Red 218, and the metal ion.

The metal complex dye may have a solubility of greater than or equal to about 5, e.g., about 5 to about 10, in a solvent used in the photosensitive resin composition according to some embodiments, e.g., the solvent described herein. The solubility may be obtained by an amount (g) of the dye dissolved in 100 g of the solvent. When the solubility of the metal complex dye is within the above ranges, compatibility with other components constituting the photosensitive resin composition according to some embodiments and coloring power may be secured, and precipitation of the dye may be prevented.

The solvent may be, e.g., propylene glycol monomethyl ether acetate (PGMEA), ethyl lactate (EL), ethylene glycol ethyl acetate (EGA), cyclohexanone (cyclohexanone), 3-methoxy-1-butanol, or a combination thereof.

The composition may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt %, based on a total weight of the photosensitive resin composition. When the metal complex dye is included in the above ranges, high luminance and contrast ratio may be exhibited in a desired color coordinate.

When the dye and the pigment are mixed and used, they may be mixed in a weight ratio of about 0.1:99.9 to about 99.9:0.1, e.g., about 1:9 to about 9:1. When mixed in the above weight ratio ranges, chemical resistance and maximum absorption wavelength may be controlled within an appropriate range, and high luminance and contrast ratio may be exhibited in a desired color coordinate.

The colorant may be included in an amount of about 30 wt % to about 80 wt %, e.g., about 40 wt % to about 70 wt %, or about 50 wt % to about 60 wt %, based on the solid content excluding the solvent, based on a total amount of the photosensitive resin composition. When the colorant is included within the above ranges, a coloring effect and developability are improved.

### [(D) Binder Resin]

The photosensitive resin composition may further include a binder resin. In an implementation, the binder resin may include an acrylic resin.

The acrylic resin may be a copolymer of a first ethylenic unsaturated monomer and a second ethylenic unsaturated monomer that is copolymerizable therewith, and may be a resin including at least one acryl repeating unit.

The first ethylenic unsaturated monomer may be an ethylenic unsaturated monomer including at least one carboxyl group and examples of the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt %, based on a total weight of the acrylic binder resin.

The second ethylenic unsaturated monomer may be an aromatic vinyl compound such as styrene, α-methylstyrene, vinyl toluene, vinylbenzylmethylether, or the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

Examples of the acrylic resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

In an implementation, the binder resin may include an epoxy binder resin.

The binder resin may help improve heat resistance by further including an epoxy binder resin. In an implementation, the epoxy binder resin may include, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, wand may help to form a pixel having a desired resolution during a developing process.

The epoxy binder resin may be included in an amount of about 1 wt % to about 10 wt %, e.g., about 5 wt % to about 10 wt %, based on a total weight of the binder resin. When the epoxy binder resin is included in the above ranges, film residue ratio and chemical resistance may be greatly improved.

An epoxy equivalent weight of the epoxy resin may be about 150 g/eq to about 200 g/eq. When an epoxy binder resin having an epoxy equivalent within the above range is included in the binder resin, there may be an advantageous effect in improving a curing degree of the formed pattern and fixing the colorant in the structure in which the pattern is formed.

The binder resin may be dissolved in a solvent in a solid form to form a photosensitive resin composition. In this case, the binder resin in the solid form may be about 10 wt % to about 50 wt %, e.g., about 20 wt % to about 40 wt %, based on a total weight of the binder resin solution dissolved in the solvent.

The binder resin may be included in an amount of about 1 wt % to about 20 wt %, e.g., about 3 wt % to about 15 wt %, or about 5 wt % to about 10 wt %, based on a total solid amount of the photosensitive resin composition. When the binder resin is included within the above ranges, it is possible to obtain excellent surface smoothness due to excellent developability and improved crosslinking property during manufacture of the color filter.

### [(E) Solvent]

The solvent may be a material that has compatibility with the colorant, the binder resin, the photopolymerizable compound, and the photopolymerization initiator but does not react.

Examples of the solvent may include alcohols such as methanol, ethanol, or the like; ethers such as dichloroethyl ether, n-butyl ether, diisoamyl ether, methylphenyl ether, tetrahydrofuran, or the like; glycol ethers such as ethylene glycol monomethylether, ethylene glycol monoethylether, or the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, or the like; propylene glycol alkylether acetates such as propylene glycol methylether acetate, propylene glycol propylether acetate, or the like; aromatic hydrocarbons such as toluene, xylene, or the like; ketones such as methylethylketone, cyclohexanone, 4-hydroxy-4-methyl-2-pentanone, methyl-n-propylketone, methyl-n-butylketone, methyl-n-amylketone, 2-heptanone, or the like; saturated aliphatic monocarboxylic acid alkyl esters such as ethyl acetate, n-butyl acetate, isobutyl acetate, or the like; lactate esters such as methyl lactate, ethyl lactate, or the like; oxy acetic acid alkyl esters such as oxy methyl acetate, oxy ethyl acetate, butyl oxyacetate, or the like; alkoxy acetic acid alkyl esters such as methoxy methyl acetate, methoxy ethyl acetate, methoxy butyl acetate, ethoxy methyl acetate, ethoxy ethyl acetate, or the like; 3-oxy propionic acid alkyl esters such as 3-oxy methyl propionate, 3-oxy ethyl propionate, or the like; 3-alkoxy propionic acid alkyl esters such as 3-methoxy methyl propionate, 3-methoxy ethyl propionate, 3-ethoxy ethyl propionate, 3-ethoxy methyl propionate, or the like; 2-oxy propionic acid alkyl esters such as 2-oxy methyl propionate, 2-oxy ethyl propionate, 2-oxy propyl propionate, or the like; 2-alkoxy propionic acid alkyl esters such as 2-methoxy methyl propionate, 2-methoxy ethyl propionate, 2-ethoxy ethyl propionate, 2-ethoxy methyl propionate, or the like; 2-oxy-2-methyl propionic acid esters such 2-oxy-2-methyl methyl propionate, 2-oxy-2-methyl ethyl propionate, or the like, monooxy monocarboxylic acid alkyl esters of 2-alkoxy-2-methyl alkyl propionates such as 2-methoxy-2-methyl methyl propionate, 2-ethoxy-2-methyl ethyl propionate, or the like; esters such as 2-hydroxy ethyl propionate, 2-hydroxy-2-methyl ethyl propionate, hydroxy ethyl acetate, 2-hydroxy-3-methyl methyl butanoate, or the like; ketonate esters such as ethyl pyruvate, or the like. In an implementation, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, or the like may be also used.

Among these, considering compatibility and reactivity, ketones such as cyclohexanone; glycol ethers such as ethylene glycol monoethyl ether; ethylene glycol alkyl ether acetates such as ethyl cellosolve acetate; esters such as 2-hydroxy ethyl propionate; carbitols such as diethylene glycol monomethyl ether; propylene glycol alkyl ether acetates such as propylene glycol monomethyl ether acetate and propylene glycol propyl ether acetate, and ketones such as cyclohexanone may be used.

The solvent may be included in a balance amount, e.g., about 5 wt % to about 70 wt %, or about 10 wt % to about 50 wt %, based on a total weight of the photosensitive resin composition. When the solvent is included within the above ranges, it is possible to obtain a coating film having excellent coatability of the photosensitive resin composition and excellent flatness.

### [(F) Other Additives]

In an implementation, the photosensitive resin composition may further include an additive, e.g., malonic acid; 3-amino-1,2-propanediol; a coupling agent including a vinyl group or a (meth)acryloxy group; a leveling agent; a surfactant; or a radical polymerization initiator, in order to prevent stains or spots during the coating, to adjust leveling, or to prevent pattern residue due to non-development.

The additives may be adjusted according to desired physical properties.

The coupling agent may be a silane coupling agent, and examples of the silane coupling agent may include trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, β epoxycyclohexyl)ethyltrimethoxysilane, which may be used alone or in mixture of 2 or more types.

The silane coupling agent may be included in an amount of about 0.01 part by weight to about 1 part by weight, based on 100 parts by weight of the photosensitive resin composition.

In an implementation, the photosensitive resin composition for color filters may further include a surfactant, e.g., a fluorine surfactant.

Examples of the fluorine surfactant may include F-482, F-484, and F-478 of DIC Co., Ltd.

The surfactant may be included in an amount of about 0.01 wt % to about 5 wt %, e.g., about 0.01 wt % to about 2 wt %, based on a total amount of the photosensitive resin composition. If the amount were to be outside of the above ranges, foreign substances could be generated after development.

In an implementation, a certain amount of other additives such as an antioxidant, a stabilizer, or the like may be added to the photosensitive resin composition within a range that does not impair physical properties.

The photosensitive resin composition may be applied to a photosensitive resin composition for a color filter of a CMOS image sensor, e.g., a photosensitive resin composition for a color filter of a CMOS image sensor.

### (Photosensitive Resin Layer, Color Filter, and CMOS Image Sensor)

The photosensitive resin composition according to some embodiments may help improve an adhesion force of the photosensitive resin composition or the photosensitive resin layer to a substrate and minimize pattern residue of the photosensitive resin layer when manufacturing a color filter.

In an implementation, the photosensitive resin composition according to some embodiments is suitable for realizing a CMOS image sensor with excellent performance.

In this regard, some embodiments provide a photosensitive resin layer manufactured using the photosensitive resin composition according to the aforementioned embodiment.

According to some embodiments, a color filter manufactured using the photosensitive resin composition according to the aforementioned embodiment may be provided.

Methods of manufacturing a photosensitive resin layer and a color filter including the same according to embodiments may be as follows.

The aforementioned photosensitive resin composition may be coated to form an about 0.5 μm to about 10 μm-thick photosensitive resin composition layer on a glass substrate in an appropriate method such as spin coating, roller coating, spray coating, and the like.

Subsequently, the substrate having the photosensitive resin composition layer is radiated by light to form a pattern required for a color filter. The radiation may be performed by using UV, an electron beam or an X-ray as a light source, and the UV may be radiated, for example, in a region of about 190 nm to about 450 nm, for example about 200 nm to about 400 nm. The radiation may be performed by further using a photoresist mask. After performing the radiation process in this way, the photosensitive resin composition layer exposed to the light source is treated with a developing solution. Herein, a non-exposure region in the photosensitive resin composition layer may be dissolved and forms the pattern for a color filter. This process may be repeated as many times as the number of necessary colors, obtaining a color filter having a desired pattern. In an implementation, when the image pattern obtained through development in the above process is cured by reheating or radiating an actinic ray thereinto, crack resistance, solvent resistance, and the like may be improved.

According to some embodiments, a CMOS image sensor including the aforementioned color filter is provided.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparation of Photosensitive Resin Compositions

### Examples 1 to 6 and Comparative Examples 1 to 5

Each photosensitive resin composition was prepared by mixing the compositions shown in Tables 1 and 2.

Specifically, after dissolving the photopolymerization initiator in the solvent, the mixture was stirred at ambient temperature for 30 minutes, and then the photopolymerizable compound was added thereto and stirred at ambient temperature for 60 minutes. Subsequently, the pigment dispersion as a colorant was added to the obtained reactants and stirred at ambient temperature for 30 minutes. Additionally, the additives were added and stirred at ambient temperature for 30 minutes. Then, each photosensitive resin composition was prepared by filtering the product twice to remove impurities.

TABLE 1
(unit: wt %)

| | | Solid | Example | Example | Example | Example | Example | Example |
|---|---|---|---|---|---|---|---|---|
| Component | Material | (%) | 1 | 2 | 3 | 4 | 5 | 6 |
| Photopolymerizable | A-1 | 100 | 1.4 | 1.26 | 1.05 | 0.98 | 0.91 | 0.875 |
| compound | A-2 | 100 | 0.5 | 0.7 | 1 | 1.1 | 1.2 | 1.25 |
| | A-3 | 100 | 0.6 | 0.54 | 0.45 | 0.42 | 0.39 | 0.375 |
| | (A-1) + (A-3) | 100 | 2 | 1.8 | 1.5 | 1.4 | 1.3 | 1.25 |
| | (A-1) + (A-2) | 100 | 1.9 | 1.96 | 2.05 | 2.08 | 2.11 | 2.125 |
| (B) | B-1 | 100 | 0.4 | 0.4 | 0.4 | 0.4 | 0.4 | 0.4 |
| Photopolymerization | | | | | | | | |
| initiator | | | | | | | | |
| (C) Colorant | C-1 | 21.27 | 43.5 | 43.5 | 43.5 | 43.5 | 43.5 | 43.5 |
| | C-2 | 19.06 | 34.1 | 34.1 | 34.1 | 34.1 | 34.1 | 34.1 |
| (D) Binder resin | D-1 | 100 | 0.5 | 0.5 | 0.5 | 0.5 | 0.5 | 0.5 |
| (E) Solvent | E-1 | — | 18.5 | 18.5 | 18.5 | 18.5 | 18.5 | 18.5 |
| (F) Additive | F-1 | 10 | 0.3 | 0.3 | 0.3 | 0.3 | 0.3 | 0.3 |
| | F-2 | 100 | 0.2 | 0.2 | 0.2 | 0.2 | 0.2 | 0.2 |

TABLE 2
(unit: wt %)

| | | | Comparative | Comparative | Comparative | Comparative | Comparative |
|---|---|---|---|---|---|---|---|
| | | Solid | Example | Example | Example | Example | Example |
| Component | Material | (%) | 1 | 2 | 3 | 4 | 5 |
| Photopolymerizable | A-1 | 100 | — | 1.75 | 0.84 | 0.7 | 0.56 |
| compound | A-2 | 100 | 2.5 | — | 1.3 | 1.5 | 1.7 |
| | A-3 | 100 | — | 0.75 | 0.36 | 0.3 | 0.24 |
| | (A-1) + (A-3) | 100 | — | 0.75 | 0.84 | 0.7 | 0.56 |
| | (A-1) + (A-2) | 100 | 40 | 40 | 40 | 40 | 40 |
| Photopolymerization | B-1 | 100 | 0.4 | 0.4 | 0.4 | 0.4 | 0.4 |
| initiator | | | | | | | |
| (C) | C-1 | 21.27 | 43.5 | 43.5 | 43.5 | 43.5 | 43.5 |
| Colorant | C-2 | 19.06 | 34.1 | 34.1 | 34.1 | 34.1 | 34.1 |
| (D) Binder resin | D-1 | 100 | 0.5 | 0.5 | 0.5 | 0.5 | 0.5 |
| (E) Solvent | E-1 | — | 18.5 | 18.5 | 18.5 | 18.5 | 18.5 |
| (F) Additive | F-1 | 10 | 0.3 | 0.3 | 0.3 | 0.3 | 0.3 |
| | F-2 | 100 | 0.2 | 0.2 | 0.2 | 0.2 | 0.2 |

Each component used in Tables 1 and 2 is as follows.

### (A) Photopolymerizable Compound

A mixed photopolymerizable compound (product name: Viscoat1000), Manufacturer: Osaka Yuki) in which (A-1) a first photopolymerizable compound represented by Chemical Formula 1 and (A-3) a third photopolymerizable compound represented by Formula 1 were mixed at a weight ratio of 7:3.

(A-2) A second photopolymerizable compound represented by Chemical Formula 2-1 (product name: dipentaerythritol hexaacrylate (DPHA), manufacturer: Nippon Kayaku Co. Ltd.)

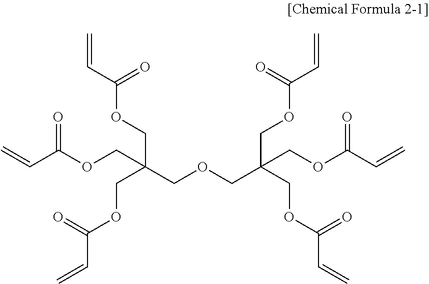 [SMILES: C=CC(=O)OCC(COCC(COC(=O)C=C)(COC(=O)C=C)COC(=O)C=C)(COC(=O)C=C)COC(=O)C=C]

### (B) Photopolymerization Initiator

### (B-1) Oxime Initiator (Product Name: OXE-01, Manufacturer: BASF)

### (C) Colorant

### (C-1) Green Pigment Dispersion (G58, Manufacturer: ENF)

### (C-2) Yellow Pigment Dispersion (Y138, Manufacturer: ENF)

### (D) Binder Resin

(D-1) Acrylic Binder Resin (Mw=8,000-12,000 g/Mol, Acid Value=100 to 140 Mgkoh/g)

### (E) Solvent

(E-1) Propylene glycolmonomethyl ether acetate (PGMEA, Manufacturer: Sigma-Aldrich Co., Ltd.)

### (F) Additives

(F-1) Fluorine-Based Surfactant (F-554, Manufacturer: DIC (Using 10% Diluted solution))

### (F-2) Silane-Based Coupling Agent (5-510, Manufacturer: CHISSO)

### (Evaluation)

### Evaluation Example 1: Adhesion Force

Each photosensitive resin composition according to Examples 1 to 6 and Comparative Examples 1 to 5 was coated to be about 0.7 μm thick on a wafer substrate with a spin coater (Opticoat MS-A150, Mikasa Co., Ltd.), soft-baked on a hot-plate at 100° C. for 180 seconds, and exposed to light with a power of 200 to 1,000 ms by using an exposer (NSR-2005i10C, Nikon Inc.).

Subsequently, the coated substrate was developed with 0.2 wt % of a TMAH aqueous solution by using a developer (SSP-200, SVS). Then, the developed substrate was hard-baked on a hot plate at 230° C. for 5 minutes.

An optical microscope (product name: BX51-N33MU, manufacturer: Olympus Corp.) was used to examine a bulk region (magnification: 2.5) and a fine pattern region (magnification: 2.5) to check adhesion force according to the following criteria, and the results are shown in Table 3. In addition, optical microscope images of Example 3 and Comparative Example 5 are representatively shown in the FIGURE.

Criteria for evaluation of adhesion force of photosensitive resin layer to substrate
⊚: Very good level of adhesion force
○: Good level of adhesion force
Δ: Medium level of adhesion force
X: Inferior level of adhesion force

### Evaluation Example 2: Pattern Residue Evaluation

The photosensitive resin compositions of Examples 1 to 6 and Comparative Examples 1 to 5 were respectively coated to be about 0.7 m thick on a wafer substrate with a spin coater (Opticoat MS-A150, Mikasa Co., Ltd.), soft-baked on a hot plate at 100° C. for 180 seconds, and exposed to light with power of 200 to 1,000 ms by using an exposer (NSR-2005i10C, Nikon inc.).

After the coating, exposure, development, hard-baking, and additional curing, a CD-SEM equipment was used to measure a 0.8 m pattern CD and thus check whether residues around the pattern were improved, and the results are shown in Table 3.

Criteria for evaluation of residue characteristics
⊚: Very good level of residues in pattern and surrounding bottoms
○: Good level of pattern residues
Δ: Medium level of pattern residues
X: Inferior level of pattern residues

### Evaluation Example 2: Evaluation of Pattern Residues

The patterns formed on the specimens obtained under the same conditions as in Evaluation Example 2 were measured using a CD-SEM device, and the results are shown in Table 3.

### <Criteria for Evaluation of Patternability>

○: The pattern profile was straight and good
x: pattern profile was inferior in linearity

TABLE 3

| | Adhesion force | Residue | Patternability |
|---|---|---|---|
| Example 1 | ◯ | ⊚ | ◯ |
| Example 2 | ⊚ | ⊚ | ◯ |
| Example 3 | ⊚ | ⊚ | ◯ |
| Example 4 | ◯ | ◯ | ◯ |
| Example 5 | ◯ | ◯ | ◯ |
| Example 6 | Δ | ◯ | ◯ |
| Comparative Example 1 | X | X | X |
| Comparative Example 2 | ◯ | ⊚ | ◯ |
| Comparative Example 3 | X | ◯ | ◯ |
| Comparative Example 4 | X | Δ | X |
| Comparative Example 5 | X | Δ | X |

By way of summation and review, a pigment dispersion method may be used to manufacture a color filter.

The pigment dispersion method may be a method of forming the color filter by coating a photosensitive resin composition including a colorant on a substrate, exposing to light a pattern to be formed, and developing it, and thermally curing it through post-baking to form a photosensitive resin layer and then, repeating this series of processes.

In this process of manufacturing the color filter, an adhesion force of the photosensitive resin composition to the substrate may affect patternability of the photosensitive resin layer. In order to help improve the adhesion force of the photosensitive resin composition to the substrate, a content of a binder resin, a photopolymerizable compound, a photopolymerization initiator, a coupling agent, or the like may be increased to enhance a curing degree of the photosensitive resin composition.

As the adhesion force of the photosensitive resin composition to the substrate is improved, an increase in pattern residues of the photosensitive resin layer could occur.

One or more embodiments may provide a photosensitive resin composition capable of improving an adhesion force of the photosensitive resin composition or photosensitive resin layer to a substrate and minimizing pattern residues of the photosensitive resin layer when manufacturing a color filter.

The photosensitive resin composition according to some embodiments may help improve an adhesion force of the photosensitive resin composition or the photosensitive resin layer to a substrate and minimize pattern residue of the photosensitive resin layer when manufacturing a color filter.

Thus, the photosensitive resin composition according to some embodiments may be suitable for realizing a CMOS image sensor with excellent performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a photopolymerizable compound;
a photopolymerization initiator;
a colorant;
a binder resin; and
a solvent,
wherein:
the photopolymerizable compound includes:
a first photopolymerizable compound having 4 functional groups,
a second photopolymerizable compound having 6 functional groups, and
a third photopolymerizable compound having 8 or more functional groups, and
the photopolymerizable compound satisfies Equation 1:
$$( x + z ) / y > 1 \qquad [ Equation 1 ]$$
in Equation 1,
x is the wt % of the first photopolymerizable compound based on a total weight of the photopolymerizable compound;
y is the wt % of the second photopolymerizable compound based on the total weight of the photopolymerizable compound; and
z is the wt % of the third photopolymerizable compound based on the total weight of the photopolymerizable compound.

2. The photosensitive resin composition as claimed in claim 1, wherein:
the photopolymerizable compound satisfies Equation 2:
$$( x + y ) / z > 1 \qquad [ Equation 2 ]$$
in Equation 2, x, y, and z are defined the same as those of Equation 1.

3. The photosensitive resin composition as claimed in claim 1, wherein a weight ratio of the first photopolymerizable compound and the third photopolymerizable compound in the photopolymerizable compound is about 9:1 to about 6:4.

4. The photosensitive resin composition as claimed in claim 1, wherein the first photopolymerizable compound is included in an amount of about 35 to about 60 wt %, the second photopolymerizable compound is included in an amount of about 35 to about 55 wt %, and the third photopolymerizable compound is included in an amount of about 10 to about 30 wt %, based on the total weight of the photopolymerizable compound.

5. The photosensitive resin composition as claimed in claim 1, wherein the photopolymerizable compound is included in an amount of about 0.1 to about 5 wt %, based on a total weight of the photosensitive resin composition.

6. The photosensitive resin composition as claimed in claim 1, wherein:
the first photopolymerizable compound is represented by Chemical Formula 1: 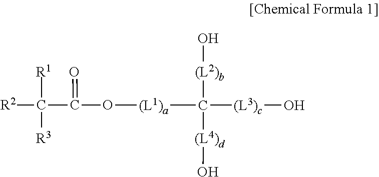
in Chemical Formula 1,
L¹ to L⁴ are each independently a C1 to C20 alkylene oxide group,
a to d are each independently an integer of 1 to 10; and
one of R¹ to R³ is hydrogen or a substituted or unsubstituted C1 to C20 alkyl, and the other two of R¹ to R³ are each independently a group represented by Chemical Formula A, in which * is a linking point, 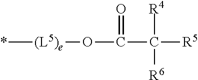
in Chemical Formula A,
L⁵ is a substituted or unsubstituted C1 to C20 alkylene group or a C1 to C20 alkylene oxide group, provided that when L⁵ is a substituted or unsubstituted C1 to C20 alkylene group, e is 1, and when L⁵ is a C1 to C20 alkylene oxide group, e is an integer of 1 to 10; and
one of R⁴ to R⁶ is hydrogen or a substituted or unsubstituted C1 to C20 alkyl group, and the other two of R⁴ to R⁶ are each independently a (meth)acrylate group.

7. The photosensitive resin composition as claimed in claim 6, wherein the first photopolymerizable compound is represented by Chemical Formula 1-1 or Chemical Formula 1-2.

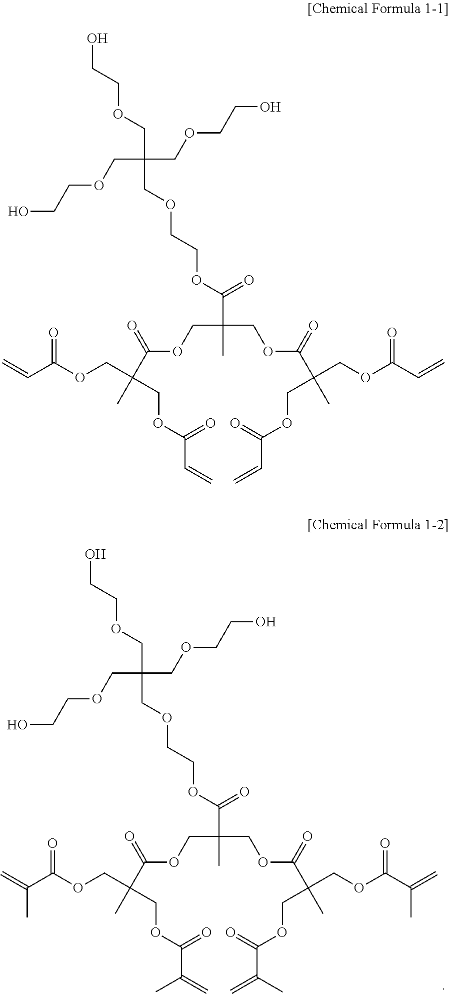

8. The photosensitive resin composition as claimed in claim 1, wherein:
the second photopolymerizable compound is represented by Chemical Formula 2: 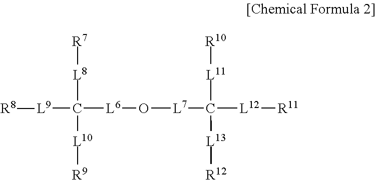
in Chemical Formula 2,
L⁶ to L¹³ are each independently a substituted or unsubstituted C1 to C20 alkylene group; and
R⁷ to R¹² are each independently a (meth)acrylate group.

9. The photosensitive resin composition as claimed in claim 8, wherein the second photopolymerizable compound is represented by Chemical Formula 2-1 or Chemical Formula 2-2:

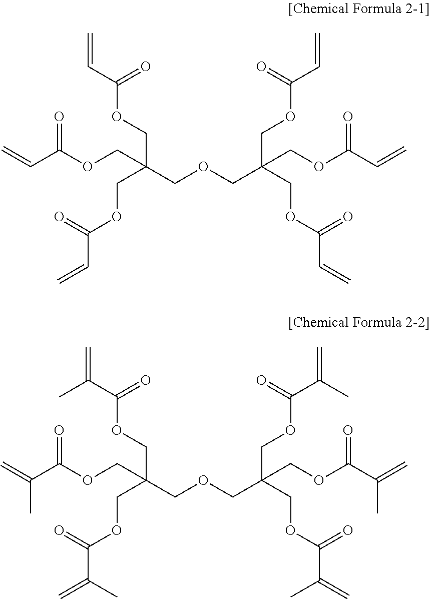

10. The photosensitive resin composition as claimed in claim 1, wherein the third photopolymerizable compound has 14 functional groups.

11. The photosensitive resin composition as claimed in claim 10, wherein:
the third photopolymerizable compound is represented by Chemical Formula 3: 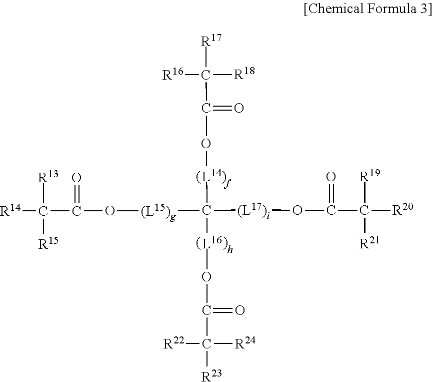
in Chemical Formula 3,
L¹⁴ to L¹⁷ are each independently a C1 to C20 alkylene oxide group,
f to i are each independently an integer of 1 to 10;
one of R¹³ to R¹⁵ is hydrogen or a substituted or unsubstituted C1 to C20 alkyl group, and the other two of R¹³ to R¹⁵ are each independently a group represented by Chemical Formula A;
one of R¹⁶ to R¹⁸ is hydrogen or a substituted or unsubstituted C1 to C20 alkyl group, another one of R¹⁶ to R¹⁸ is a group represented by Chemical Formula A, and another one of R¹⁶ to R¹⁸ is a group represented by Chemical Formula B;
one of R¹⁹ to R²¹ is hydrogen or a substituted or unsubstituted C1 to C20 alkyl group, and the other two of R¹⁹ to R²¹ are each independently a group represented by Chemical Formula A; and
one of R²² to R²⁴ is hydrogen or a substituted or unsubstituted C1 to C20 alkyl group, another one of R²² to R²⁴ is a group represented by Chemical Formula A, and another one of R²² to R²⁴ is a group represented by Chemical Formula B, 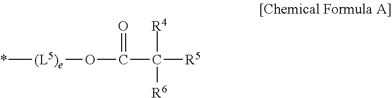
in Chemical Formula A,
L⁵ is a substituted or unsubstituted C1 to C20 alkylene group or a C1 to C20 alkylene oxide group, provided that when L⁵ is a substituted or unsubstituted C1 to C20 alkylene group, e is 1, and when L⁵ is a C1 to C20 alkylene oxide group, e is an integer of 1 to 10; and
one of R⁴ to R⁶ is hydrogen or a substituted or unsubstituted C1 to C20 alkyl group, and the other two of R⁴ to R⁶ are each independently a (meth)acrylate group, 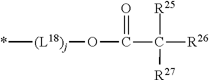
in Chemical Formula B,
L¹⁸ is a substituted or unsubstituted C1 to C20 alkylene group or a C1 to C20 alkylene oxide group, provided that when L¹⁸ is a substituted or unsubstituted C1 to C20 alkylene group, j is 1, and when L¹⁸ is a C1 to C20 alkylene oxide group, j is an integer of 1 to 10; and
one of R²⁵ to R²⁷ is hydrogen or a substituted or unsubstituted C1 to C20 alkyl group, another one of R²⁵ to R²⁷ is a C1 to C20 alkyl group substituted with a hydroxy group at a terminal end, and another one of R²⁵ to R²⁷ is a (meth)acrylate group.

12. The photosensitive resin composition as claimed in claim 11, wherein the third photopolymerizable compound is represented by Chemical Formula 3-1 or Chemical Formula 3-2:

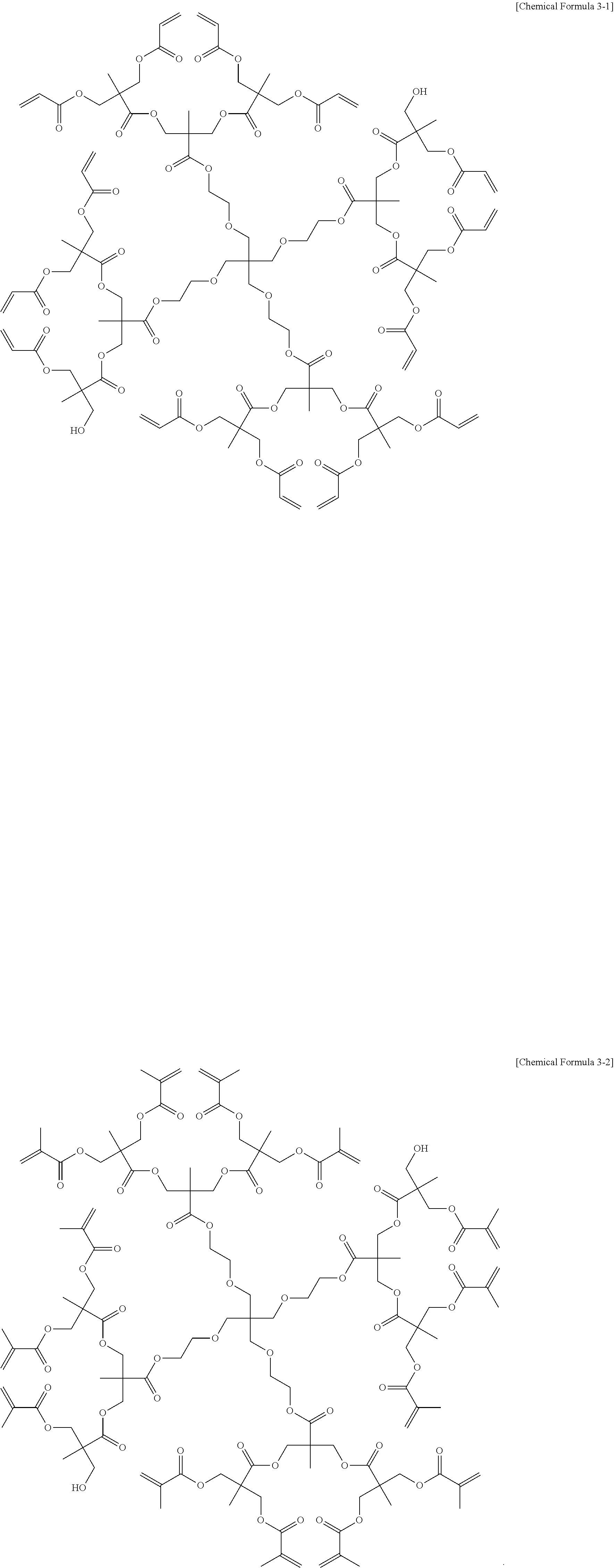

13. The photosensitive resin composition as claimed in claim 1, wherein the colorant includes a pigment.

14. The photosensitive resin composition as claimed in claim 13, wherein the pigment includes a green pigment, a yellow pigment, or a mixture thereof.

15. The photosensitive resin composition as claimed in claim 1, wherein the binder resin includes an acrylic binder resin.

16. The photosensitive resin composition as claimed in claim 1, wherein the photosensitive resin composition includes:
about 0.1 wt % to about 5 wt % of the photopolymerizable compound;
about 0.1 wt % to about 5 wt % of the photopolymerization initiator;
about 30 wt % to about 80 wt % of the colorant;
about 1 wt % to about 20 wt % of the binder resin; and
the solvent, all wt % being based on a total weight of the photosensitive resin composition.

17. A photosensitive resin layer manufactured using the photosensitive resin composition as claimed in claim 1.

18. A color filter comprising a photosensitive resin layer as claimed in claim 17.

19. A CMOS image sensor comprising the color filter as claimed in claim 18.
